(19) United States
(12) Patent Application Publication
(10) Pub. No.: US 2008/0093681 A1
(43) Pub. Date: Apr. 24, 2008

(54) Semiconductor device and method for fabricating the same

(76) Inventor: Yoshihiro Sato, Hyogo (JP)

Correspondence Address: MCDERMOTT WILL & EMERY LLP, 600 13TH STREET, NW, WASHINGTON, DC, 20005-3096, US

(21) Appl. No.: 11/806,886

(22) Filed: Jun. 5, 2007

(30) Foreign Application Priority Data
Oct. 20, 2006 (JP) JP 2006-286253

(51) Int. Cl. H01L 21/336; H01L 29/76

(52) U.S. Cl. 257/412; 438/294; 257/E29.226; 257/E21.409

(57) ABSTRACT

A semiconductor device includes: a semiconductor substrate; an isolation region formed on a semiconductor substrate, the top surface of the isolation region being located above the top surface of the semiconductor substrate; a fully silicided gate line continuously formed to cover part of the top surface of an active region of the semiconductor substrate surrounded by the isolation region and part of the top surface of the isolation region; and an insulative sidewall formed on a side of the gate line. The vertical length of a part of the sidewall on the isolation region is different from that of a part of the sidewall on the active region.

### CROSS-REFERENCE TO RELATED APPLICATIONS

The disclosure of Japanese Patent Application No. 2006-286253 filed on Oct. 20, 2006 including specification, drawings and claims is incorporated herein by reference in its entirety.

### BACKGROUND OF THE INVENTION

(1) Field of the Invention

The present invention relates to semiconductor devices and methods for fabricating the same, and more particularly relates to semiconductor devices in which gate electrodes are fully silicided and methods for fabricating the same.

(2) Description of Related Art

With recent advances in techniques for enabling increases in the degree of integration, functionality and speed of semiconductor integrated circuit devices, metal insulator semiconductor field effect transistors (MISFETs) have decreased in size. With this decrease in MISFET size, gate insulating films have become progressively thinner. At the same time, in order to restrain the gate leakage current from increasing due to tunnel current, a technique has been studied in which when a high-dielectric-constant material made of a metal oxide, such as hafnium dioxide (HfO₂), a hafnium silicate (HfSiO) film or a hafnium silicate nitride (HfSiON) film is used instead of SiO₂ or SiON that has conventionally been used as a material of a gate insulating film, this keeps the physical thickness of the gate insulating film large while achieving a thin equivalent silicon oxide thickness, thereby suppressing the leakage current. There have been many studies on a technique in which a metal material is used, as a material of a gate electrode, instead of polysilicon that has conventionally been used thereas to prevent the capacitance of the gate electrode from being reduced due to depletion of the gate electrode. Examples of such a metal material include metal nitride, dual metal made of two types of pure metals having different work functions, and fully silicided (FUSI) materials formed by changing the entire gate lines into silicide. In particular, attention is given on full silicidation as a promising technique because current silicon processing techniques are still used. The structure of a MISFET in which a fully silicided material is used and a method for fabricating the MISFET have been disclosed in, for example, K. G. Anil et al., Symp. VLSI Tech., 2004, p. 190 and A. Veloso et al., IEDM Tech. Dig., 2004, p. 855.

However, the present inventor found the following problems of the known MISFET in which a fully silicided material is used. The problems will be described hereinafter with reference to the drawings.

FIGS. 4A through 4C and 5A and 5B are cross-sectional views illustrating the problems in a known method for fabricating a semiconductor device.

In the known fabrication method, first, the following process step is carried out to provide the structure illustrated in FIG. 4A. More particularly, an isolation region 102 is selectively formed in the top surface of a semiconductor substrate 100 to electrically isolate devices from one another. The isolation region 102 is formed such that its top surface is above the top surface of the semiconductor substrate 100.

Subsequently, an active region 101 is formed in the semiconductor substrate 100 by implanting ions into the semiconductor substrate 100. Subsequently, a gate insulating film formation film is formed on the semiconductor substrate 100, and then a gate electrode formation film and a protective film for protecting the gate electrode formation film are sequentially deposited to cover the gate insulating film formation film and the isolation region 102. Thereafter, the gate insulating film formation film, the gate electrode formation film and the protective film are patterned into a gate insulating film 103a, a gate electrode 104a, a gate line 104b, and protective films 105a and 105b by photolithography and dry etching. Immediately after this patterning, since the top surface of the isolation region 102 is above the top surface of the semiconductor substrate 100, the gate line 104b and the protective film 105b are formed at a higher level than the gate electrode 104a and the protective film 105a, respectively.

Next, shallow source/drain diffusion layers 106a are formed in the active region 101 by ion implantation using the gate electrode 104a, the gate line 104b, and the protective films 105a and 105b as masks.

Next, the following process step is carried out to provide the structure illustrated in FIG. 4B. More particularly, an insulating film is deposited to cover the semiconductor substrate 100, the protective films 105a and 105b, the gate electrode 104a, and the gate line 104b. The deposited insulating film is etched back, thereby forming sidewalls 107 on both sides of a combination of the protective film 105a and the gate electrode 104a and both sides of a combination of the protective film 105b and the gate line 104b. Subsequently, impurity ions are implanted into the active region 101 using the gate electrode 104a, the gate line 104b, the protective films 105a and 105b, and the sidewalls 107 as masks, thereby forming deep source/drain diffusion layers 106b in regions of the active region 101 located to the outer sides of the associated sidewalls 107. Thereafter, the semiconductor substrate 100 is subjected to heat treatment to activate the impurity.

Subsequently, a native oxide film formed on the top surfaces of the deep source/drain diffusion layers 106b is removed, and then, for example, an 11-nm-thick metal film (not shown) made of nickel is deposited by sputtering to cover the semiconductor substrate 100. Subsequently, the semiconductor substrate 100 is subjected to the first rapid thermal annealing (RTA) at 320° C. in a nitrogen atmosphere. In this way, silicon is caused to react with the metal film, thereby changing the top surfaces of the deep source/drain diffusion layers 106b into nickel silicide. Subsequently, unreacted part of the metal film left on the isolation region 102, the protective film 105a, the protective film 105b, and the sidewalls 107 is removed by soaking the semiconductor substrate 100 in an etchant containing a mixed acid of hydrochloric acid and a hydrogen peroxide solution or the like. Thereafter, the semiconductor substrate 100 is subjected to the second RTA at a higher temperature than the temperature at which the first RTA is conducted (for example, 550° C.). In this way, low-resistance silicide layers 108 are formed in the top surfaces of the deep source/drain diffusion layers 106b. Subsequently, a 20-nm-thick silicon nitride film 109 is deposited by chemical vapor deposition (CVD) or any other method to cover the semiconductor substrate 100. An interlayer dielectric 110 made of, for example, a silicon oxide film is formed to cover the deposited silicon nitride film 109. Subsequently, the top surface of the interlayer dielectric 110 is planarized by a chemical mechanical polishing (CMP) method.

Next, in the process step illustrated in FIG. 4C, the interlayer dielectric 110 is partially removed by dry etching or wet etching until the silicon nitride film 109 is exposed. Conditions for this dry or wet etching are set to provide a high selectivity with respect to a silicon nitride film. Unless the interlayer dielectric 110 is sufficiently overetched in the above-mentioned removal, a part of the silicon nitride film 109 formed on the protective film 105a associated with the active region 101 will not be exposed. The reason for this is that there is a difference in level between the top surface of a part of the silicon nitride film 109 located on the active region 101 and the top surface of a part thereof located on the isolation region 102.

Next, in the process step illustrated in FIG. 5A, parts of the silicon nitride film 109 formed on the protective films 105a and 105b are etched by dry etching or wet etching to expose the top surfaces of the protective films 105a and 105b. Conditions for this dry or wet etching are set to provide a high selectivity with respect to a silicon oxide film. However, if as illustrated in FIG. 4C the part of the silicon nitride film 109 formed on the protective film 105a associated with the active region 101 is not exposed, the top surface of the protective film 105a will not be able to be exposed in this process step. In order to avoid this problem, in the process step illustrated in FIG. 4C, the part of the silicon nitride film 109 formed on the protective film 105a need be exposed with reliability. If, in order to satisfy the need, the interlayer dielectric 110 is excessively overetched, the remaining part of the interlayer dielectric 110 will become thin. Accordingly, when the silicon nitride film 109 is etched in the process step illustrated in FIG. 5A, parts of the silicon nitride film 109 formed on the silicide layers 108 may also be etched, resulting in the silicide layers 108 exposed.

Next, in the process step illustrated in FIG. 5B, the protective films 105a and 105b formed on the gate electrode 104a and the gate line 104b are removed by dry etching or wet etching to expose the gate electrode 104a and the gate line 104b. Conditions for this dry or wet etching are set to provide a high selectivity with respect to a silicon nitride film and a polysilicon film. However, since the protective film 105a and the silicon nitride film 109 are present on the gate electrode 104a, the top surface of the gate electrode 104a will not be able to be exposed. Therefore, the gate electrode 104a will not be able to be fully silicided. Furthermore, when in the process step illustrated in FIG. 4C the interlayer dielectric 110 is excessively overetched in order to certainly expose the part of the silicon nitride film 109 located on the protective film 105a associated with the active region 101, the parts of the silicon nitride film 109 located on the silicide layers 108 may also be etched away in the process step illustrated in FIG. 5A to thereby expose the silicide layers 108, and thus the silicide layers 108 may be partially or totally etched away simultaneously with removal of the protective films 105a and 105b in the same process step. In addition, when the gate electrode 104a and the gate line 104b are fully silicided, the thickness of each silicide layer 108 may increase, leading to an increase in the leakage current.

### SUMMARY OF THE INVENTION

The present invention is made to solve the above-mentioned problems, and its object is to provide a semiconductor device achieving full silicidation of a gate electrode with higher reliability and a method for fabricating the same.

In order to achieve the above-mentioned object, a semiconductor device of the present invention includes: a semiconductor substrate; an isolation region formed on a semiconductor substrate, the top surface of the isolation region being located above the top surface of the semiconductor substrate; a fully silicided gate line continuously formed to cover part of the top surface of an active region of the semiconductor substrate surrounded by the isolation region and part of the top surface of the isolation region; and an insulative sidewall formed on a side of the gate line, the vertical length of a part of the sidewall on the isolation region being different from that of a part of the sidewall on the active region.

The semiconductor device of the present invention can be fabricated in the following method. More particularly, a gate line formation film and a protective film formation film are formed to cover the active region of the semiconductor substrate and the isolation region, and then the top surface of the protective film formation film is planarized. Thereafter, the gate line formation film and the protective film formation film are patterned into the gate line and the protective film. The sidewall is formed on the side of a combination of the gate line and the protective film. Thereafter, an interlayer dielectric is formed to cover the protective film and the sidewall.

In such fabrication process steps, parts of the protective film located on the active region and the isolation region are located at the same level (vertical location). Therefore, when the interlayer dielectric is gradually removed in a later process step, parts of the protective film located on the active region and the isolation region, respectively, are both easily exposed. This allows parts of the gate line on both the regions to be fully silicided with higher reliability. Furthermore, since as in the known art etching does not need to be excessively performed to expose parts of the protective film on both the regions, this can prevent silicide on the active region from being exposed.

In the semiconductor device of the present invention, a level difference may be produced between the active region and the isolation region, and the difference in vertical length between the part of the sidewall on the isolation region and the part of the sidewall on the active region may be substantially equal to the level difference.

In the semiconductor device of the present invention, the top end of the part of the sidewall on the isolation region may be located at the same level as the top end of the part of the sidewall on the active region.

In the semiconductor device of the present invention, a part of the gate line located on the isolation region and a part of the gate line located on the active region may have substantially the same composition.

In the semiconductor device of the present invention, a part of the gate line located on the active region may serve as a gate electrode section, and a gate insulating film may be interposed between the gate electrode section and the active region.

In the semiconductor device of the present invention, impurity diffusion layers may be formed in parts of the active region located to both sides of the gate electrode section.

The semiconductor device of the present invention may further include an insulating film covering the sidewall, and an interlayer dielectric covering the insulating film and the top surface of the gate line.

In the semiconductor device of the present invention, a stressor film may be interposed between the insulating film and the interlayer dielectric.

A method for fabricating a semiconductor device of the present invention includes the steps of: (a) forming an isolation region on a semiconductor substrate, the top surface of the isolation region being located above the semiconductor substrate; (b) after the step (a), sequentially forming a gate insulating film formation film, a gate line formation film and a protective film formation film on the semiconductor substrate; (c) polishing the protective film formation film by chemical mechanical polishing, thereby reducing the level difference formed in the surface of the protective film formation film; (d) after the step (c), patterning the gate insulating film formation film, the gate line formation film and the protective film formation film into a gate insulating film, a gate line and a protective film; (e) forming a sidewall on a side of a combination of the gate insulating film, the gate line and the protective film; (f) after the step (e), forming an interlayer dielectric to cover the semiconductor substrate, the protective film and the sidewall; (g) partially removing the interlayer dielectric until the top surface of the protective film is exposed; (h) after the step (g), removing the protective film to expose the gate line; and (i) fully siliciding the gate line.

In such fabrication process steps, parts of the protective film located on the active region and the isolation region are located at substantially the same level (vertical location). Therefore, when the interlayer dielectric is gradually removed in a later process step, parts of the protective film located on the active region and the isolation region, respectively, are both easily exposed. This allows parts of the gate line on both the regions to be fully silicided with higher reliability. Furthermore, since as in the known art etching does not need to be excessively performed to expose parts of the protective film on both the regions, this can prevent silicide on the active region from being exposed.

In the method of the present invention, in the step (h), etching may be used to remove the protective film.

The method of the present invention may further include the steps of (j) after the step (d) and before the step (e), implanting ions into an active region of the semiconductor substrate surrounded by the isolation region using the gate line and the protective film as masks, thereby forming first source/drain regions in regions of the active region located to both sides of the gate line, and (k) after the step (e) and before the step (f), implanting ions into the active region using the gate line, the protective film and the sidewall as masks, thereby forming second source/drain regions in regions of the active region located to both outer sides of the sidewall.

In the method of the present invention, in the step (b), the protective film formation film may be formed to have a larger thickness than the level difference between the semiconductor substrate and the isolation region.

In the method of the present invention, the gate line may be a polysilicon film or an amorphous silicon film.

In the method of the present invention, the protective film may be a silicon oxide film.

In the method of the present invention, the metal film may contain at least one selected from the group of nickel, cobalt, platinum, titanium, ruthenium, iridium, ytterbium, and a transition metal.

In the method of the present invention, the gate insulating film may be a high-dielectric-constant film having a dielectric constant of 10 or more.

In the method of the present invention, the gate insulating film formation film may be a film containing a metal oxide.

In the method of the present invention, the gate insulating film formation film may be a film containing at least one selected from the group of aluminum and a transition metal.

As described above, according to the semiconductor device of the present invention and the fabrication method for the same, the level difference between parts of the protective film located on parts of the gate electrode formation film on the active region and the isolation region, respectively, is reduced. This facilitates planarizing the interlayer dielectric and allows the gate line to be exposed with high accuracy by etching the interlayer dielectric.

### BRIEF DESCRIPTION OF THE DRAWINGS

FIGS. 1A through 1E are cross-sectional views illustrating process steps in a fabrication method for a semiconductor device according to an embodiment of the present invention.

FIGS. 2A through 2D are cross-sectional views illustrating other process steps in the fabrication method for a semiconductor device according to the embodiment of the present invention.

FIGS. 3A through 3C are cross-sectional views illustrating still other process steps in the fabrication method for a semiconductor device according to the embodiment of the present invention.

FIGS. 4A through 4C are cross-sectional views illustrating a problem in a known fabrication method for a semiconductor device.

FIGS. 5A and 5B are cross-sectional views illustrating the other problems in the known fabrication method for a semiconductor device.

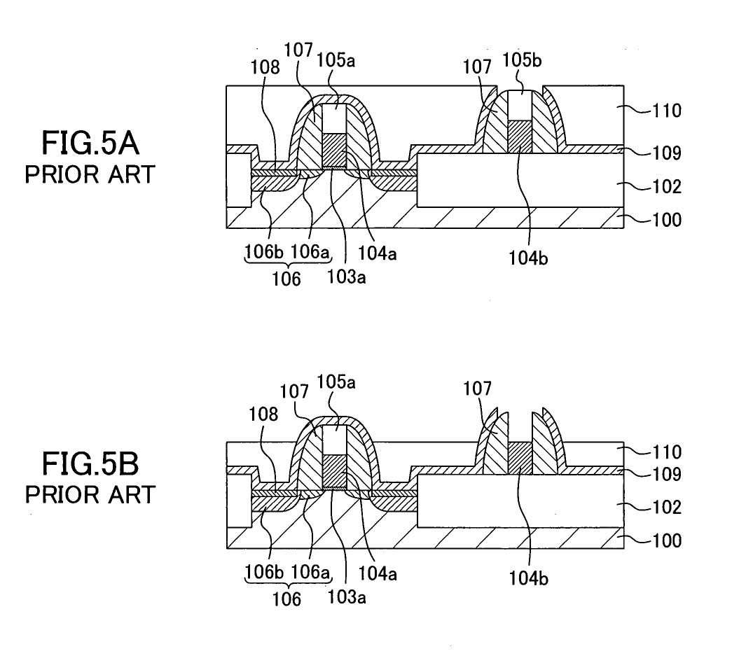

### DETAILED DESCRIPTION OF THE INVENTION

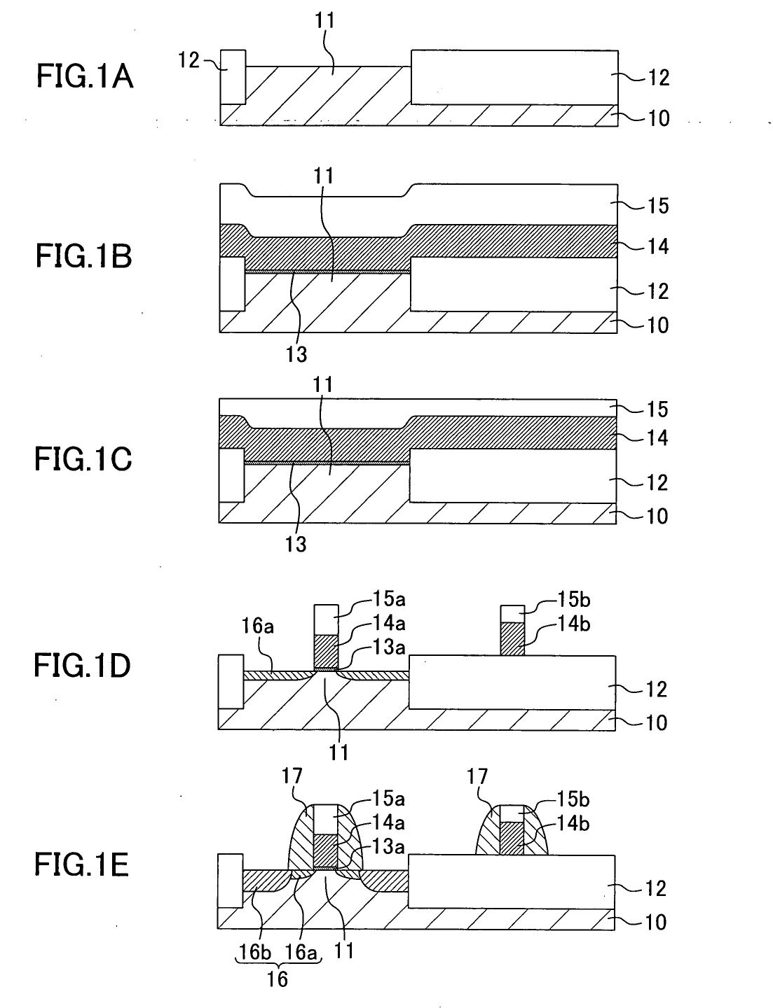

An embodiment of the present invention will be described with reference to the drawings. FIGS. 1A through 1E, 2A through 2D, and 3A through 3C are cross-sectional views illustrating process steps in a fabrication method for a semiconductor device according to the embodiment of the present invention.

In the fabrication method for a semiconductor device according to the embodiment of the present invention, first, in the process step illustrated in FIG. 1A, an isolation region 12 is formed on a semiconductor substrate 10 made of, for example, p-type silicon by a shallow trench isolation (STI) method or any other method to electrically isolate devices from one another. In this case, the top surface of the isolation region 12 is located, for example, approximately 20 nm above the top surface of the semiconductor substrate 10. The level difference between the isolation region 12 and the semiconductor substrate 10 is usually, for example, larger than 0 nm and equal to or smaller than 50 nm. Next, an active region (well) 11 is formed in the semiconductor substrate 10 by implanting ions into the semiconductor substrate 10.

Next, in the process step illustrated in FIG. 1B, a 2-nm-thick gate insulating film formation film 13 made of silicon oxide is formed in a region of the principal surface of the semiconductor substrate 10 surrounded by the isolation region 12, i.e., the top surface of the active region 11, for example, by dry oxidation, wet oxidation, oxidation using radical oxygen or the like. Subsequently, a 100-nm-thick gate line formation film 14 that is made of polysilicon and will become a gate electrode and a gate line is deposited by CVD or any other method to cover the isolation region 12 and the gate insulating film formation film 13. Next, a 100-nm-thick protective film formation film 15 made of a silicon oxide film is formed by CVD or any other method to cover the gate line formation film 14. Immediately after the formation of the protective film formation film 15, the difference in level between the top surfaces of parts of the protective film formation film 15 on the active region 11 and the isolation region 12 is produced due to the difference in level between the active region 11 and the isolation region 12.

Next, in the process step illustrated in FIG. 1C, the top surface of the protective film formation film 15 is planarized by CMP. In this manner, the level of the top surface of a part of the protective film formation film 15 on the active region 11 is allowed to become equal to that of the top surface of a part thereof on the isolation region 12. Thus, the top surface of the protective film formation film 15 becomes flat. In this process step, the top surface of the protective film formation film 15 need not necessarily be completely flat. The reason for this is that although in the present invention the level difference formed in the surface of the protective film formation film 15 is preferably eliminated, the level difference formed in the surface of the protective film formation film 15 need only become smaller than that between the active region 11 and the isolation region 12 to provide an effect.

Next, in the process step illustrated in FIG. 1D, the gate insulating film formation film 13, the gate line formation film 14 and the protective film formation film 15 are selectively etched by photolithography and dry etching. In this manner, a gate insulating film 13a, a gate electrode section 14a, and a protective film 15a are formed on the active region 11, and a gate line section 14b and a protective film 15b are formed on the isolation region 12. A structure partially forming the gate electrode section 14a and a structure partially forming the gate line section 14b are referred to as “gate lines” in this specification and claims. In other words, a part of each of the gate lines located on the active region 11 is referred to as a “gate electrode section”, and a part of the gate line located on the isolation region 12 is referred to as a “gate line section”. Subsequently, ions are implanted into the active region 11 using the gate electrode section 14a and the protective film 15a as masks, thereby forming first source/drain diffusion layers 16a serving as shallow source/drain diffusion layers in regions of the active region 11 located to both sides of the gate electrode section 14a.

Next, in the process step illustrated in FIG. 1E, for example, a 50-nm-thick silicon nitride film is deposited by CVD or any other method to entirely cover the semiconductor substrate 10. Thereafter, the deposited silicon nitride film is subjected to anisotropic etching, thereby leaving only parts of the silicon nitride film formed on the lateral sides of a combination of the gate electrode section 14a and the protective film 15a and the lateral sides of a combination of the gate line section 14b and the protective film 15b. In this way, sidewalls 17 are formed on the lateral sides of the combinations. Subsequently, impurity ions are implanted into the active region 11 using the associated sidewalls 17 as masks, and then the active region 11 is subjected to heat treatment, thereby forming second source/drain diffusion layers 16b serving as deep source/drain diffusion layers in regions of the active regions 11 located to the outer sides of the associated sidewalls 17.

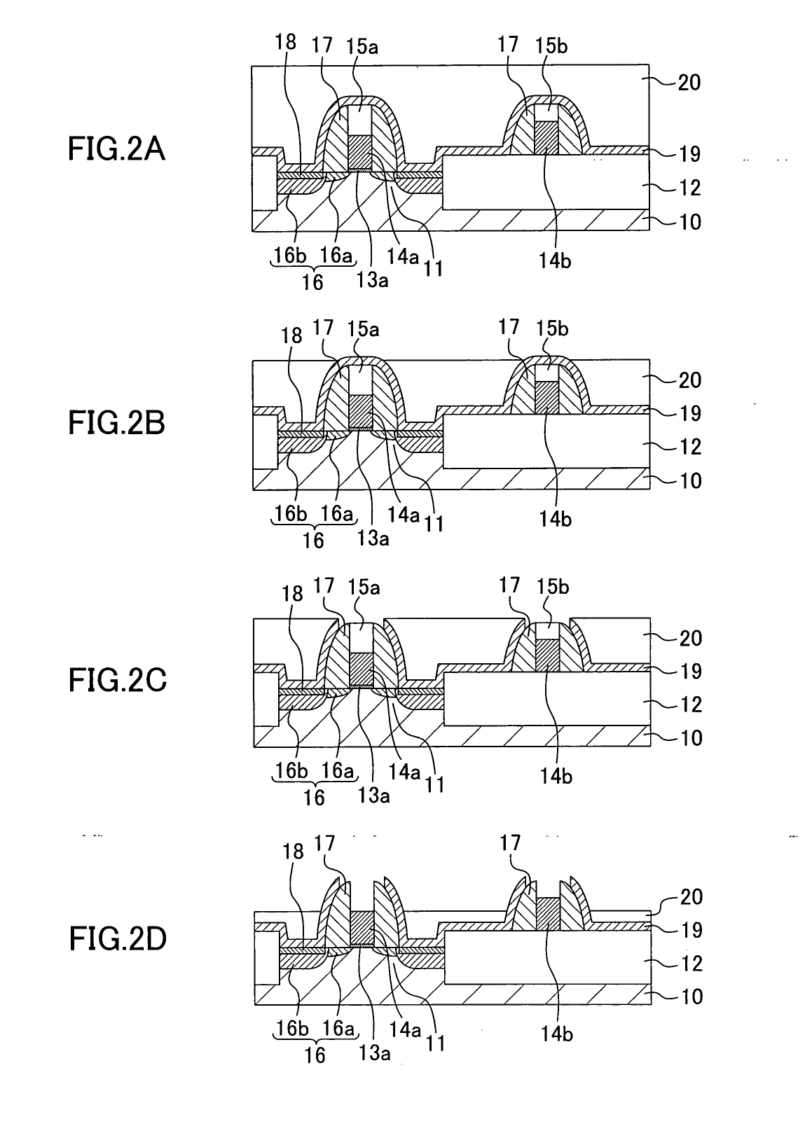

Next, in the process step illustrated in FIG. 2A, a native oxide film is removed from the top surfaces of the second source/drain diffusion layers 16b, and then an 11-nm-thick metal film (not shown) made of nickel is deposited by sputtering or any other method to cover the semiconductor substrate 10. Subsequently, the semiconductor substrate 10 is subjected to the first RTA at 320° C. in a nitrogen atmosphere. In this way, silicon is caused to react with the metal film, thereby changing the top surfaces of the second source/drain diffusion layers 16b into nickel silicide. Subsequently, unreacted part of the metal film left on the isolation region 12, the protective film 15a, the protective film 15b, and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 550° C.). In this way, low-resistance silicide layers 18 are formed in the top surfaces of the second source/drain diffusion layers 16b. Subsequently, a 20-nm-thick silicon nitride film 19 is deposited by CVD or any other method to cover the semiconductor substrate 10. A first interlayer dielectric 20 made of, for example, a silicon oxide film is formed to cover the deposited silicon nitride film 19. Subsequently, the top surface of the first interlayer dielectric 20 is planarized by CMP. Use of CMP facilitates planarizing the first interlayer dielectric 20 and enhances the uniformity of the first interlayer dielectric 20.

Next, in the process step illustrated in FIG. 2B, the first interlayer dielectric 20 is etched by dry etching or wet etching until the silicon nitride film 19 is exposed. Conditions for this dry or wet etching are set to provide a high selectivity with respect to a silicon nitride film. In this case, while CMP is used in the process step illustrated in FIG. 2A, etching is used in the process step illustrated in FIG. 2B. However, CMP may be used in both the process steps. Alternatively, the first interlayer dielectric 20 may be etched back partway, and then the remaining part of the first interlayer dielectric 20 may be etched.

Next, in the process step illustrated in FIG. 2C, parts of the silicon nitride film 19 located on the protective films 15a and 15b are etched by dry etching or wet etching. Conditions for this dry or wet etching are set to provide a high selectivity with respect to a silicon oxide film. In the above-mentioned manner, the top surfaces of the protective films 15a and 15b are exposed.

Next, in the process step illustrated in FIG. 2D, the protective films 15a and 15b are removed by dry etching or wet etching. Conditions for this dry or wet etching are set to provide a high selectivity with respect to a silicon nitride film and a polysilicon film. In the above-mentioned manner, the gate electrode section 14a and the gate line section 14b are exposed.

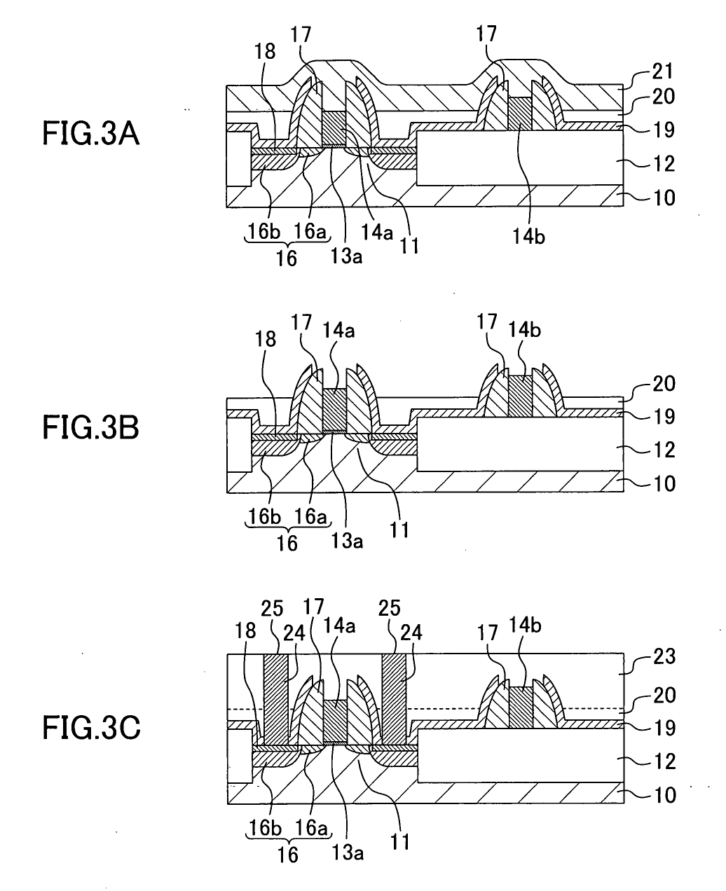

Next, in the process step illustrated in FIG. 3A, a 70-nm-thick metal film 21 made of nickel is deposited, for example, by sputtering to cover the first interlayer dielectric 20, the gate electrode section 14a and the gate line section 14b. Subsequently, the semiconductor substrate 10 is subjected to the first RTA at 380° C. in a nitrogen atmosphere, thereby changing the gate electrode section 14a and the gate line section 14b into silicide.

Next, in the process step illustrated in FIG. 3B, unreacted part of the metal film 21 left on the first interlayer dielectric 20, the silicon nitride film 19, and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 500° C.). In this way, the gate electrode section 14a and the gate line section 14b are fully silicided. Since the gate electrode section 14a and the gate line section 14b are formed by patterning a single film and then being subjected to the same processes, they have substantially the same composition. “The gate electrode section 14a and the gate line section 14b are fully silicided” means that the gate electrode section 14a and the gate line section 14b are completely changed into silicide and is distinguished from a case where only the top surfaces of the gate electrode section 14a and the gate line section 14b are changed into silicide.

Next, in the process step illustrated in FIG. 3C, a second interlayer dielectric 23 is formed, for example, by CVD or any other method to cover the first interlayer dielectric 20. Then, the top surface of the second interlayer dielectric 23 is planarized by CMP.

Next, a resist mask pattern (not shown) is formed on the second interlayer dielectric 23, and contact holes 24 are formed by dry etching using the resist mask pattern to partially expose the top surfaces of the silicide layers 18 located in the top surfaces of the source/drain diffusion layers. In this formation of the contact holes 24, use of a two-step etching method in which etching is once suspended at the time of exposure of the silicon nitride film 19 can reduce the amount of the silicide layers 18 overetched.

Next, titanium and titanium nitride are sequentially deposited, as a barrier metal film for tungsten, by sputtering or CVD to fill parts of the contact holes 24, and further tungsten is deposited by CVD to fill the other parts of the contact holes 24. Then, the deposited tungsten is subjected to CMP, thereby removing part of the deposited tungsten located outside the contact holes 24. In this manner, contact plugs 25 are formed. The above-described process steps lead to the formation of the semiconductor device of this embodiment.

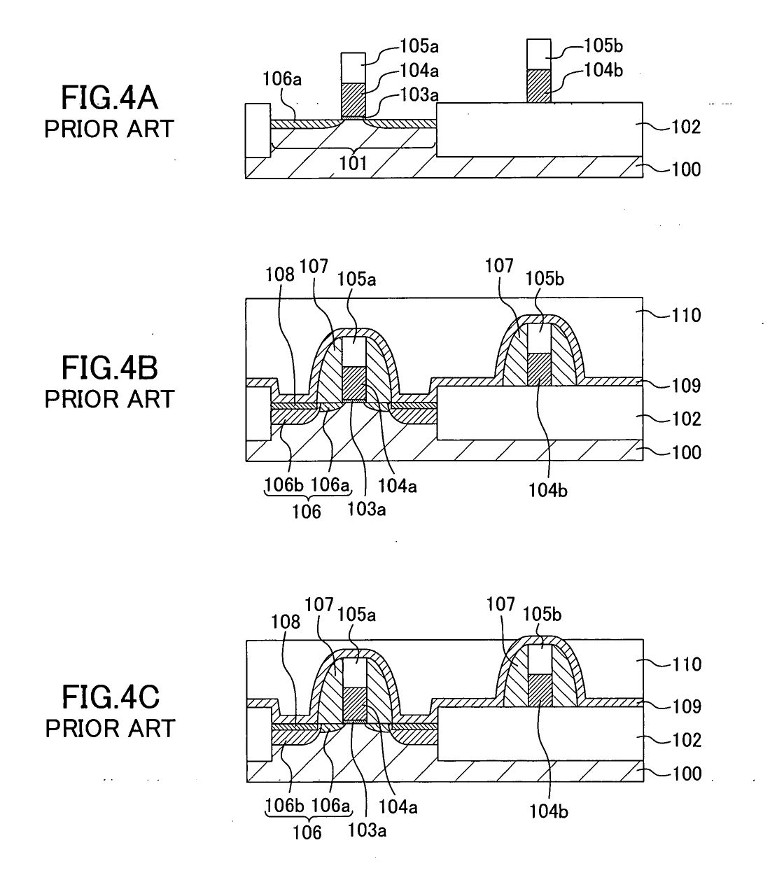

In a semiconductor device fabricated by the above-described method, as illustrated in FIG. 3C, the vertical length of each of sidewalls 17 on an active region 11 is different from that of each of sidewalls 17 on an isolation region 12. The vertical length of the sidewall 17 on the active region 11 means the distance between the top surface of the semiconductor substrate 10 and the top end of the sidewall 17. The vertical length of the sidewall 17 on the isolation region 12 means the distance between the top surface of the isolation region 12 and the top end of the sidewall 17. More particularly, in the known art, as illustrated in FIG. 4B, the vertical length of each of sidewalls 107 on an active region 101 is equal to that of each of sidewalls 107 on an isolation region 102. On the other hand, since, in the process step illustrated in FIG. 1C in this embodiment, the top surface of a protective film formation film 15 is planarized, the vertical length of each of sidewalls 17 formed in the process step illustrated in FIG. 1C and located on an active region 11 is different from that of each of sidewalls 17 formed in the same process step and located on an isolation region 12. The difference in vertical length between the sidewall 17 on the active region 11 and the sidewall 17 on the isolation region 12 is produced due to the level difference between the active region 11 and the isolation region 12. For this reason, the difference in level between the sidewalls 17 becomes substantially equal to the level difference between the active region 11 and the isolation region 12. Furthermore, in the process step illustrated in FIG. 1E, the top surface of a protective film 15a associated with the active region 11 is located at the same level as the top surface of a protective film 15b associated with the isolation region 12. Therefore, the top end of each of the sidewalls 17 formed on the lateral sides of a combination of a gate electrode section 14a and the protective film 15a on the active region 11 is located at the same level (vertical location) as that of each of the sidewalls 17 formed on the lateral sides of a combination of a gate line section 14b and the protective film 15b on the isolation region 12.

According to this embodiment, the top surfaces of parts of a silicon nitride film 19 formed on protective films 15a and 15b are at the same level. Therefore, when in the process step illustrated in FIG. 2B an interlayer dielectric 20 is etched to expose the above-mentioned top surfaces, the top surfaces of the parts of the silicon nitride film 19 formed on the protective films 15a and 15b associated with the active region 11 and the isolation region 12, respectively, can be exposed at substantially the same time. Accordingly, in the process step illustrated in FIG. 2C, parts of the silicon nitride film 19 located on the protective films 15a and 15b associated with the active region 11 and the isolation region 12, respectively, can both be removed, and in the process step illustrated in FIG. 2D, the protective films 15a and 15b associated with the active region 11 and the isolation region 12, respectively, can be removed. Furthermore, unlike the known art, a silicon nitride film does not need to be excessively etched in order to expose protective films associated with both the active and isolation regions. This can prevent silicide in the active region from being also exposed.

Although in the above description a gate insulating film 13a is formed of silicon oxide, a high-dielectric-constant film may be alternatively used as a material of the gate insulating film 13a. When a high-dielectric-constant film is used for a FUSI gate electrode structure as described above, the threshold voltage can be controlled by changing the silicide content of a material of a FUSI gate electrode. As the high-dielectric-constant film, use can be made of a film of hafnium-based oxide, such as a hafnium dioxide (HfO₂) film, a hafnium silicate (HfSiO) film, or a nitrided hafnium silicate (HfSiON) film. Other than these films, a high-dielectric-constant film made of a material containing at least one of zirconium (Zr), titanium (Ti), tantalum (Ta), aluminum (Al), rare-earth metal including scandium (Sc), yttrium (Y), lanthanum (La), and other lanthanoids, and the like may be used.

Although in this embodiment a gate electrode formation film 14 is formed of polysilicon, it may be alternatively formed of any other semiconductor material containing amorphous silicon or silicon.

Although nickel is used as a metal for forming silicide layers 18, a metal for silicidation, such as cobalt, titanium, or tungsten, may be used instead.

Although nickel is used as a metal for fully siliciding a gate electrode section 14a and a gate line section 14b, a metal for full silicidation, which contains at least one selected from the group of cobalt, platinum, titanium, ruthenium, iridium, ytterbium, and a transition metal, may be used instead.

Furthermore, although sidewalls 17 are formed of a silicon nitride film, they may be formed by stacking a silicon oxide film and a silicon nitride film.

Although in the above description an interlayer dielectric 23 is formed to cover a fully silicided gate electrode section 14a, a fully silicided gate line section 14b and a silicon nitride film 19, a stressor film made of a nitride film or any other material may be interposed between the interlayer dielectric 23 and a combination of the fully silicided gate electrode section 14a, the fully silicided gate line section 14b and the silicon nitride film 19. In this case, after in the process step illustrated in FIG. 3B a first interlayer dielectric 20 is removed to completely expose the silicon nitride film 19, a stressor film need be formed to cover the fully silicided gate electrode section 14a, the fully silicided gate line section 14b and the silicon nitride film 19. Thereafter, like the process step illustrated in FIG. 3C, a second interlayer dielectric 23 may be deposited to cover the stressor film.

As described above, a semiconductor device of the present invention and a fabrication method for the same have the effect of reducing the level difference between parts of a protective film formation film located on parts of a gate electrode formation film on an active region and an isolation region, respectively, to facilitate planarizing an interlayer dielectric, and, when the interlayer dielectric is etched to expose a gate electrode section and a gate line section, exposing the gate electrode section and the gate line section with high accuracy, and are useful as a semiconductor device in which a gate electrode is fully silicided and a fabrication method for the same.

What is claimed is:

1. A semiconductor device comprising:
a semiconductor substrate;
an isolation region formed on a semiconductor substrate, the top surface of the isolation region being located above the top surface of the semiconductor substrate;
a fully silicided gate line continuously formed to cover part of the top surface of an active region of the semiconductor substrate surrounded by the isolation region and part of the top surface of the isolation region; and
an insulative sidewall formed on a side of the gate line, the vertical length of a part of the sidewall on the isolation region being different from that of a part of the sidewall on the active region.

2. The semiconductor device of claim 1, wherein
a level difference is produced between the active region and the isolation region, and
the difference in vertical length between the part of the sidewall on the isolation region and the part of the sidewall on the active region is substantially equal to the level difference.

3. The semiconductor device of claim 1, wherein
the top end of the part of the sidewall on the isolation region is located at the same level as the top end of the part of the sidewall on the active region.

4. The semiconductor device of claim 1, wherein
a part of the gate line located on the isolation region and a part of the gate line located on the active region have substantially the same composition.

5. The semiconductor device of claim 1, wherein
a part of the gate line located on the active region serves as a gate electrode section, and
a gate insulating film is interposed between the gate electrode section and the active region.

6. The semiconductor device of claim 5, wherein
impurity diffusion layers are formed in parts of the active region located to both sides of the gate electrode section.

7. The semiconductor device of claim 1 further comprising
an insulating film covering the sidewall, and
an interlayer dielectric covering the insulating film and the top surface of the gate line.

8. The semiconductor device of claim 7, wherein
a stressor film is interposed between the insulating film and the interlayer dielectric.

9. A method for fabricating a semiconductor device, said method comprising the steps of:
(a) forming an isolation region on a semiconductor substrate, the top surface of the isolation region being located above the semiconductor substrate;
(b) after the step (a), sequentially forming a gate insulating film formation film, a gate line formation film and a protective film formation film on the semiconductor substrate;
(c) polishing the protective film formation film by chemical mechanical polishing, thereby reducing the level difference formed in the surface of the protective film formation film;
(d) after the step (c), patterning the gate insulating film formation film, the gate line formation film and the protective film formation film into a gate insulating film, a gate line and a protective film;
(e) forming a sidewall on a side of a combination of the gate insulating film, the gate line and the protective film;
(f) after the step (e), forming an interlayer dielectric to cover the semiconductor substrate, the protective film and the sidewall;
(g) partially removing the interlayer dielectric until the top surface of the protective film is exposed;
(h) after the step (g), removing the protective film to expose the gate line; and
(i) fully siliciding the gate line.

10. The method of claim 9, wherein
in the step (h), etching is used to remove the protective film.

11. The method of claim 9 further comprising the steps of
(j) after the step (d) and before the step (e), implanting ions into an active region of the semiconductor substrate surrounded by the isolation region using the gate line and the protective film as masks, thereby forming first source/drain regions in regions of the active region located to both sides of the gate line, and
(k) after the step (e) and before the step (f), implanting ions into the active region using the gate line, the protective film and the sidewall as masks, thereby forming second source/drain regions in regions of the active region located to both outer sides of the sidewall.

12. The method of claim 9, wherein
in the step (b), the protective film formation film is formed to have a larger thickness than the level difference between the semiconductor substrate and the isolation region.

13. The method of claim 9, wherein
the gate line is a polysilicon film or an amorphous silicon film.

14. The method of claim 9, wherein
the protective film is a silicon oxide film.

15. The method of claim 9, wherein
the metal film contains at least one selected from the group of nickel, cobalt, platinum, titanium, ruthenium, iridium, ytterbium, and a transition metal.

16. The method of claim 9, wherein
the gate insulating film is a high-dielectric-constant film having a dielectric constant of 10 or more.

17. The method of claim 9, wherein
the gate insulating film formation film is a film containing a metal oxide.

18. The method of claim 9, wherein
the gate insulating film formation film is a film containing at least one selected from the group of aluminum and a transition metal.
